(19) United States
(12) Patent Application Publication
(10) Pub. No.: US 2026/0359504 A1
(43) Pub. Date: Nov. 12, 2026

(54) ENERGY PERFORMANCE PREDICTION ALGORITHM FOR WIND-INDUCED DAMAGE ON A BUILDING ENVELOPE

(71) Applicant: UNIVERSITY OF FLORIDA RESEARCH FOUNDATION, INCORPORATED, Gainesville, FL (US)

(72) Inventors: Ryan SHARSTON, Gainesville, FL (US); Imad Alhayik, Gainesville, FL (US); Arthriya Subgranon, Gainesville, FL (US)

(21) Appl. No.: 19/265,274

(22) Filed: Jul. 10, 2025

Related U.S. Application Data
(60) Provisional application No. 63/801,432, filed on May 7, 2025.

(51) Int. Cl. G06F 30/13

(52) U.S. Cl. CPC G06F 30/13

(57) ABSTRACT

A method for accessing energy performance due to wind-induced damage on a building envelope for a building includes performing a hazard analysis for a hazard intensity, performing an aerodynamic analysis to evaluate how wind assessments interact with the building envelope, and performing a structural analysis to assess how the building envelope responds to wind-induced loads. A damage analysis is performed to evaluate wind-induced damage to the building envelope in response to the wind-induced loads. An energy analysis is performed after the hazard intensity has ended. Performing the energy analysis includes determining post recovery weather conditions for a recovery period, performing an aerodynamic analysis to evaluate how the post recovery weather conditions interact with openings in the building envelope based on the wind-induced damage, determining airflow within the building envelope based on the wind-induced damage, and estimating energy consumption by the building envelope based on the airflow.

### RELATED APPLICATION

The present application claims the benefit of U.S. Provisional Patent Application Ser. No. 63/801,432 filed May 7, 2025, which is incorporated herein by reference in its entirety.

### TECHNICAL FIELD

The present disclosure relates to energy consumption in buildings, and more particularly, to predicting energy consumption in a building based on wind-induced damage to the building envelope.

### BACKGROUND

For almost two decades, attempts have been made to promote lessening energy consumption for buildings, given that the U.N. Environment Program states that buildings account for around 37% of CO₂ emissions and more than 34% of the world's energy use. At the present time, energy efficiency in buildings remains a pressing issue, particularly in regions prone to extreme weather conditions. Buildings consume a significant amount of energy when they are in the operation phase, which contributes to greenhouse gas emissions. In the US Energy Information Administration report, commercial buildings are estimated to account for 25% of total energy consumption on average between 2024 and 2050. As a result, excessive energy consumption leads to a rise in carbon dioxide and other greenhouse gas emissions, which is projected to increase globally at an annual rate of 1.5%. This is a major concern because these greenhouse gases contribute to global warming and climate change.

In order to fully understand the energy demands in buildings, energy consumption, usually described as heating/cooling (HVAC), equipment and lighting, is consumed during the operation phase. Considering that the great majority of energy used by buildings is used to regulate indoor temperature (heating and/or cooling) and air quality (ventilation). On an annual basis, during the summer in tropical regions, the extreme thermal temperature hits new highs, making the climate hotter and more unbearable, which leads to 20% of buildings' overall power consumption being attributable to cooling loads. Since the building envelope acts as a barrier dividing the indoor and outdoor environments, insufficient insulation and air infiltration, among additional factors, cause the building envelope to lose or gain most of the heat and cold. Thus, when the building envelope components are lost or damaged by the extreme wind event, it will significantly influence energy efficiency and indoor air environment conditions.

### SUMMARY

A method for accessing energy performance due to wind-induced damage on a building envelope for a building includes performing a hazard analysis on the building envelope using site-specific data and probabilistic wind assessments for a hazard intensity. An aerodynamic analysis is performed to evaluate how the probabilistic wind assessments interact with the building envelope, and a structural analysis is performed to assess how the building envelope responds to wind-induced loads. The method includes performing a damage analysis to evaluate wind-induced damage to the building envelope in response to the wind-induced loads.

After the damage analysis, an energy analysis is performed. The energy analysis includes determining post recovery weather conditions for a recovery period after the hazard intensity has ended, and performing an aerodynamic analysis to evaluate how the post recovery weather conditions interact with openings in the building envelope based on the wind-induced damage. An airflow within the building envelope is determined based on the wind-induced damage. Energy consumption by the building envelope based on the airflow is then estimated.

The hazard intensity has a set timeframe associated therewith, and an average wind speed at a height of the building is determined for the set timeframe.

The aerodynamic analysis, the structural analysis and the damage analysis may be iteratively performed over a timeframe set for a duration of the hazard intensity.

The aerodynamic analysis and the structural analysis may be performed in parallel, with data from the structural analysis being provided to the aerodynamic analysis, and with data from the aerodynamic analysis being provided to the structural analysis.

The aerodynamic analysis determines pressure external to the building envelope and pressure internal to the building envelope during the hazard intensity, and the structural analysis determines a drift of the building during the hazard intensity. Openings in the building as determined by the damage analysis may be fed back into the aerodynamics analysis for updating.

The post recovery weather conditions include an external air pressure and varying wind patterns.

The estimated energy consumption provides for design of an HVAC system for the building optimized for both energy efficiency and resilience in response to wind-induced damage.

The method includes determining the cost of building envelope enhancement based on the damage analysis, and determining an energy consumption cost based on the estimated energy consumption change as a result of wind-induced damage building envelope damage.

The building envelope separates an inside of the building from an environment outside of the building. The hazard intensity may correspond to a hurricane category classification.

The aerodynamic analysis determines how a distribution of pressure on external surfaces of the building envelope varies based on wind speed and direction.

The energy analysis uses an internal pressure model to access internal air infiltration when the building experiences damages that allows air to enter through the damaged components of the building envelope.

Another aspect is directed to a computing device that includes a memory configured to store a building envelope for a building, and an energy performance prediction algorithm for wind-induced building damage. A processor is coupled to the memory and is configured to execute the energy performance prediction algorithm to perform a hazard analysis on the building envelope using site-specific data and probabilistic wind assessments for a given hazard intensity, perform an aerodynamic analysis to evaluate how the probabilistic wind assessments interact with the building envelope, and perform a structural analysis to assess how the building envelope responds to wind-induced loads. A damage analysis may then be performed to evaluate wind-induced damage to the building envelope in response to the wind-induced loads.

An energy analysis is performed by determining post recovery weather conditions for a recovery period after the hazard intensity has ended, performing an aerodynamic analysis to evaluate how the post recovery weather conditions interact with openings in the building envelope based on the wind-induced damage, and determining airflow within the building envelope based on the wind-induced damage. Energy consumption by the building envelope based on the wind-induced damage is estimated. A display is coupled to the processor and is configured to display the estimated energy consumption by the building envelope based on the airflow.

Yet another aspect is directed to a non-transitory computer readable medium having computer-executable instructions for causing a computing system to access energy performance due to wind-induced damage on a building envelope for a building, with the computing system to perform the above method steps.

### BRIEF DESCRIPTION OF THE DRAWINGS

FIG. 1 is a block diagram of a computing system for accessing energy performance due to wind-induced damage on a building envelope in which various aspects of the disclosure may be implemented.

FIG. 2 is a flow diagram of the energy performance prediction algorithm for wind-induced building damage illustrated in FIG. 1.

FIG. 3 is a more detailed flowchart for the energy performance prediction algorithm illustrated in FIG. 2.

FIG. 4 is a top view of an example air flow pattern using an airflow network model based on open and closed windows for a building corresponding to the building envelope illustrated in FIG. 1.

FIG. 5A is a three-dimensional (3D) view of the building corresponding to the building envelope illustrated in FIG. 1.

FIG. 5B is a surface layout of the building illustrated in FIG. 5A with wind attack angle direction.

FIG. 6 shows post-event wind-induced damage to the building illustrated in FIG. 5A.

FIG. 7 shows post-event wind-induced damage to the building illustrated in FIG. 5A with an enhanced building envelope.

FIG. 8 is an energy consumption stacked barchart for three different design scenarios in which various aspects of the disclosure may be implemented.

FIG. 9 is a comparison of peak cooling load and total HVAC energy consumption during hurricane season for three different design scenarios in which various aspects of the disclosure may be implemented.

### DETAILED DESCRIPTION

The present description is made with reference to the accompanying drawings, in which exemplary embodiments are shown. However, many different embodiments may be used, and thus the description should not be construed as limited to the particular embodiments set forth herein. Rather, these embodiments are provided so that this disclosure will be thorough and complete. Like numbers refer to like elements throughout.

In terms of building performance, a building incorporates a wide variety of variables that impact daily life and health in areas that are vulnerable to extreme weather. According to the National Oceanic and Atmospheric Administration (NOAA), major landed tropical cyclones have an expected cost of $22 billion per event. This highlights the notable economic vulnerability associated with these tropical cyclones. When it comes to the direct impact of extreme wind events, buildings are perhaps the most vital sector. Moreover, the building performance of commercial and residential mid/high-rise structures, which often surpass three floors, are constructed with reinforced concrete and/or steel, resulting in minor structural damage from wind and debris impact. Considering that an important knowledge gap regarding how building envelope components affect overall energy performance has been highlighted by the increasing focus on building performance. Hence, evaluating the vulnerability associated with the building envelope can be done by assessing the building performance impacted by an extreme wind event to estimate the anticipation of energy consumption.

Building energy consumption has been one of the major focuses in global sustainability efforts. Most efforts to cut building energy consumption have been directed toward the utilization of energy-efficient systems and technologies. Many of these initiatives tend to overlook the challenges that come from external hazards like extreme wind events. Such events can significantly impact a building's energy performance by damaging essential materials. Since building envelopes serve as protective barriers against environmental factors like heat and air, they play a crucial role in determining energy demands.

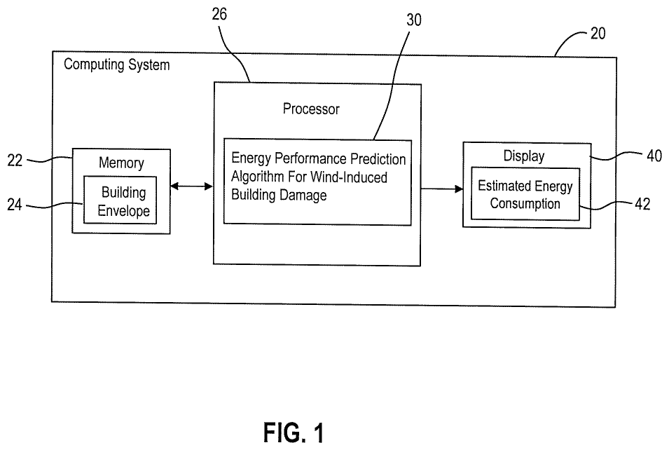

Referring initially to FIG. 1, a computing device 20 is configured to execute an energy performance prediction model 30. The energy performance prediction algorithm 30 links Performance-Based Wind Engineering (PBWE) and energy consumption analysis. This integration provides a holistic methodology for assessing the effects of wind-induced damage on a building's post-hazard energy performance. The energy performance prediction algorithm 30 advantageously creates a robust methodology for the measurement of building energy performance after an extreme wind event strikes, feeding input for improving design, retrofit, and operating practices to increase resilience and sustainability.

The computing device 20 includes a memory 22 to store a building envelope 24 of the building under consideration. The building envelope 24 includes dimensions of the building and elements such as the roof, walls, windows, doors and foundation. A processor 26 is coupled to the memory 22 and is configured to execute the energy performance prediction algorithm 30. A display 40 is coupled to the processor 26 and is configured to display the estimated energy consumption 42 by the building envelope based on the wind-induced damage.

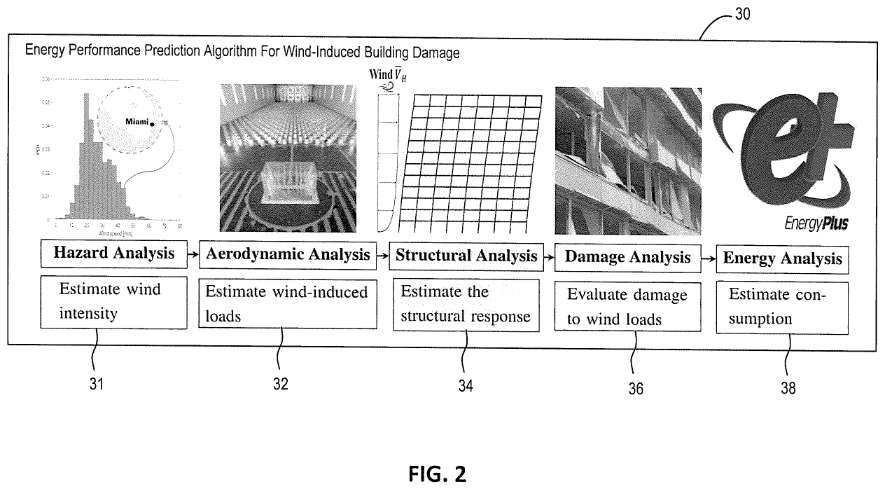

A flow diagram of the energy performance prediction algorithm 30 at a high level includes several interconnected stages designed to assess the performance of the building envelope 24 under extreme wind conditions and its subsequent energy demand, as illustrated in FIG. 2. The stages include a hazard analysis 31, an aerodynamic analysis 32, a structural analysis 34, a damage analysis 36 and an energy analysis 38.

The hazard analysis 31 is performed on the building envelope 24 using site-specific data and probabilistic wind assessments for a given hazard intensity to anticipate the wind event intensity over the life span of the building. The hazard intensity may correspond to a hurricane category classification, for example. The hazard analysis also determines a mean wind speed at the height of the building.

The aerodynamic analysis 32 is performed to evaluate how the probabilistic wind assessments interact with the building envelope 24. This analysis helps determine the wind-induced forces, pressures and potential damage mechanisms that impact the building's post-extreme wind event. To capture how the wind interacts with the building, wind tunnel testing or computational fluid dynamics (CFD) simulations are commonly used to study airflow behavior around a structure (i.e., the external pressure coefficient C_{p,e}). In particular, this analysis helps to evaluate the distribution of pressure on the building surface based on wind speed, direction and building geometry. Once the distribution of pressure is known, internal air infiltration (i.e., flow rate Q or internal pressure coefficients C_{p,i}) can be assessed using an updateable dynamic internal pressure model when a building experiences damage that allows air to enter through the damaged building envelope components.

The structural analysis 34 is performed to assess how the building envelope 24 responds to wind-induced loads, particularly during extreme wind events such as hurricanes. This analysis determines the structural integrity of the building envelope 24 and its components, linking wind-induced forces to another damage mechanisms. The aerodynamic analysis 32 and structure analysis 34 inform the damage analysis through probabilistic damage models by linking pressure coefficients, building responses, and wind speeds to failure probabilities of building envelope components.

The damage analysis 36 is performed to evaluate wind-induced damage to the building envelope 24 in response to the wind-induced loads. This analysis establishes the relationship between wind loads, structural response, and damage consequences, which ultimately influence a building's energy performance.

The energy analysis 38 is performed to estimate energy consumption by the building envelope 24 based on the wind-induced damage. In this analysis, the examination from the damage analysis 36 is then integrated with energy consumption models, such as EnergyPlus. EnergyPlus is a whole-building energy simulation program developed by the U.S. Department of Energy. It is an open-source software used by engineers, architects, and researchers to model and predict building energy consumption. EnergyPlus can simulate a wide range of building energy-related aspects, including heating, cooling, ventilation, lighting, and water use.

The damage estimates are integrated into an airflow network model within the energy analysis 38 to quantify the impact of compromised building envelope integrity on air infiltration rates to quantify the impact of building envelope damage on post extreme wind event energy demands. A Monte Carlo uncertainty analysis is used to capture the variability and uncertainty in extreme wind event scenarios and their impact on building energy demand.

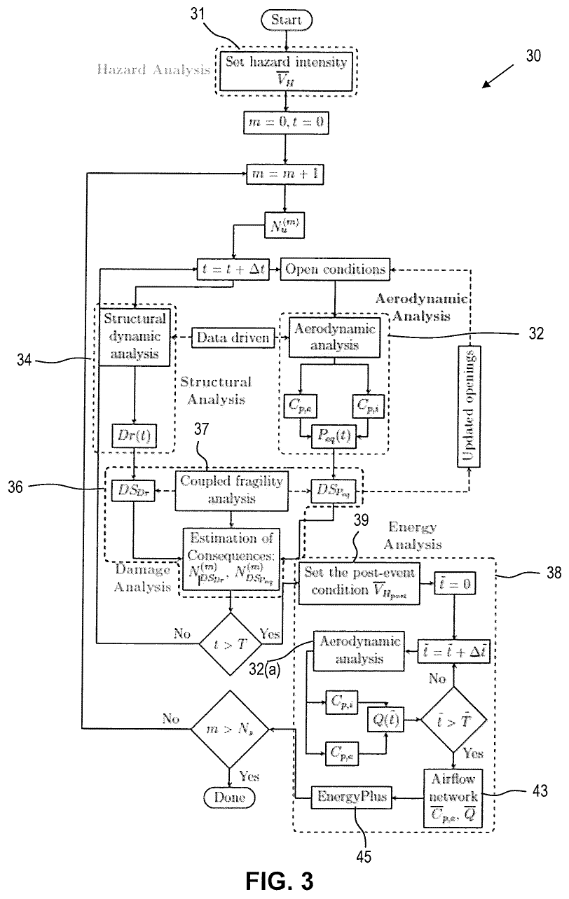

To further elaborate on the energy performance prediction algorithm 30, reference is directed to a more detailed flowchart of the simulation strategy of the energy performance prediction algorithm 30 illustrated in FIG. 3. This flowchart represents a simulation strategy of the Monte Carlo algorithm. The overall simulation algorithm can be summarized as follows.

The energy performance prediction algorithm 30 integrates different stages of analysis and handles uncertainties in the building envelope performance for estimating energy consumption through a probabilistic approach. The simulation strategy begins with identifying the hazard intensity of the extreme wind event in terms of the mean wind speed at the height of the building VH for site-specific information. Iterative time-stepping (Δt) is used to simulate the dynamic interactions of wind-induced pressure and structural response. For each stochastic wind realization m=1, . . . , Ns (Ns=total number of realization), a random vector Nᵤ^{(m)} stated is generated to introduce variability in the fragility thresholds of envelope components. The threshold Nᵤ^{(m)} vector is used to evaluate the extent of probability damage states progress for the envelope components (i.e., N_{DS}_{_{Dr}} for dynamic response and N_{DS}_{_{Peq}} for equivalent pressure).

The data driven from wind-tunnel-informed stochastic wind loads was utilized to capture structural and aerodynamic responses that would impact each time step. The structural dynamic analysis 34 assesses the structure response drift ratio Dr (t) due to wind-induced forces. Simultaneously, the aerodynamic analysis 32 calculates equivalent pressures P_{eq} resulting from the external pressure coefficients C_{p,e} and the dynamics internal pressure C_{p,i} acting on the building envelope. Open conditions representing leaks or holes due to the loss or damage of the building envelope are updated dynamically C_{p,i} based on the number of the anticipated conditions of the building envelope components.

In the coupled fragility analysis stage 37, the probability of damage is quantified using predefined fragility models where the results of the structural and aerodynamic analysis overlap to estimate the number of components in damage states Nr^{(m)}_{DS}_{_{Dr}}, and N^{(m)}_{DS}_{_{Peq}} for each realization m. Once the total time of the event T has been reached, the simulation proceeds to calculate the loss analysis in terms of energy consumption.

To compute the energy consumption post-event in the energy analysis 38, the post-event condition (i.e., the mean wind speed at the height of the building post-crisis period V_{H}_{ₚₒₛₜ}) is identified in Block 39. The post event condition may also be referred to as post recovery weather conditions, and this is defined for a recovery period after the hazard intensity has ended. The weather conditions include an external air pressure and varying wind patterns. In order to evaluate the air infiltration caused by the loss or damage of the building envelope N^{(m)}_{DS}_{_{Dr}}, and N^{(m)}_{DS}_{_{Peq}}, the aerodynamic analysis is used again to compute the air flow rate post-crisis period, as indicated by reference 32(a). The aerodynamic analysis 32(a) evaluates how the post recovery weather conditions interact with openings in the building envelope based on the wind-induced damage.

The results from the aerodynamic analysis 32(a) are then fed into the airflow network model 43 to determine airflow within the building envelope based on the wind-induced damage, and to an EnergyPlus 45 model to estimate energy consumption by the building envelope based on the airflow and the wind-induced damage. As the simulation advances, the algorithm 30 determines whether there are more realizations m than Nₛ. Otherwise, the simulation iterates over a new set of a random vector Nᵤ^{(m)} input and updated system states before advancing to the subsequent realization.

The flowchart for this algorithm visually represents these stages, ensuring a systematic and reproducible approach to assessing post extreme wind event energy demands in buildings. This methodology can be implemented in any building, location and enable decision-makers to better understand how building vulnerabilities influence operational energy performance and resilience strategies.

### Problem Setting

The main goal of energy performance prediction algorithm 30 is to evaluate the expected energy consumption of a building due to damage or loss of its envelope components by an extreme wind event. This evaluation leverages performance-based wind engineering, which ensures the achievement of a set of probabilistic descriptions of performance levels that can be clarified to decision-makers in terms of meaningful measurements. The integral is based on the total probability theorem with a number of conditional joint probability density functions to estimate the expected energy consumption. Mathematically, the expected energy consumption can be described through the following multi-dimensional integral based on the total probability theorem:

[symbol]

[EC|im]=∫∫∫∫ec·p(ec|dm)·p(dm|edp)·p(edp|ip)·

·p(ip|im)·p(im)dec ddm dedp dip (1)

E[EC|im] is the expected energy consumption conditioned on the intensity measure, im, of the design wind event; EC represents the building energy consumption; im denoted as wind intensity measure (e.g., wind speed associated with a specific mean recurrence interval (MRI)); interaction parameter ip defines the aerodynamic of building and wind field interaction usually captured through wind tunnel testing or computational fluid dynamics; engineering demand parameters edp defines critical structural responses (e.g., inter-story drift ratios); damage measure dm determines the state of damage to the building envelope components (e.g., glass cracking, glass falling); while p(a|b) represents a conditional probability density function of a conditioned on b. It should be noted that in practice, ip, edp, and dm are vectors that collect multiple components of the stochastic wind pressure process, engineering demands, and component damage conditions, respectively. Therefore, the integral of equation (1) can have a very large dimension.

### Methodology Overview

Due to the high-dimensional uncertain space of equation (1), numerical simulation methods are viable solution strategy. In this study, the Monte Carlo simulation is adopted due to its versatility and insensitivity to high-dimensional spaces. The Monte Carlo estimator can be used to estimated the expected energy consumption of equation (1) as follows:

$$𝔼 [ EC \vert im ] = \frac{1}{{N}_{s}} {\sum }_{m = 1}^{{N}_{s}} {ec}_{m} ( im ) \qquad ( 2 )$$

where Nₛ is the total number of realizations in the Monte Carlo simulation, m indicates a particular realization number, and ecₘ denotes the mth realization of the building energy consumption.

### Energy Consumption

In regions with severe weather conditions, the significant energy quantity lost across various commercial, industrial, and residential sectors is more readily evident as a result of highly different changes in indoor and outdoor temperature. In order to address this, the building envelope represents the separation of indoor and outdoor environments, which influences changes in heating/cooling and internal pressure. Therefore, when the building envelope components are lost or damaged by the extreme wind event, it will significantly influence energy efficiency and outdoor air infiltration. This assessment can be accomplished by analyzing the energy performance impacted by an extreme wind event. A general function that describes the energy consumption ecₘ calculation in energy modeling can be expressed as:

ecₘ=f(B,W,S,C_{Q}) (3)

The variable B is building and system properties, including both building geometry, material properties, and HVAC system efficiency (i.e., wall/roof construction, window properties, HVAC system type, etc.). The variable W is weather data (i.e., outdoor temperature, wind speed, etc.). The variable S is glazing properties represents window characteristics, including glazing type, solar transmittance, and thermal conductance (i.e., U-Value). The variable C_{Q} is air mass flow coefficient which describes airflow through the building envelope, influenced by infiltration, and leakage paths. Therefore, in order to calculate the energy consumption post-event due to heat gains from S and C_{Q}, a model that takes into consideration outdoor air infiltration through each lost or damaged cladding component is required.

### Building Envelope and Solar Radiation Penetration

Damage to the building envelope can lead to unintended openings that let uncontrolled solar radiation in. Accounting for a damaged envelope in energy modeling requires adjusting solar radiation transmittance, U-values, and surface properties to accurately capture the increased heat gain and energy transfer. The perfectly clear glazing concept in DesignBuilder software may be adopted to consider solar radiation penetration. This concept allows direct solar radiation and visible light to pass into the interior, influencing indoor temperatures and energy demands. Perfectly clear windows maximize solar heat gain. The thermal conductance (U-value) of this glazing is 3.12 W/m²K.

The variable S must consider whether an opening condition meets its criteria (e.g., the building envelope is damaged). If the condition is satisfied, the glazing properties adjust adequately, such as the U-value and solar heat gain coefficient (SHGC). Otherwise, the original glazing properties remain unchanged.

$$S = \{ \begin{matrix}( {SC}_{damaged} , {U}_{damaged} ) & if Ψ > {Ψ}_{c} \\ ( {SC}_{no damage} , {U}_{no damage} ) & otherwise\end{matrix} \qquad ( 4 )$$

The variable ψ represents the damage factor (e.g., damage state resulted from drift-induced damage or pressure induced damage failure, etc.) The variable ψ_{c} is the critical threshold beyond which damage occurs (e.g., no damage resulting in a component). The variables SC_{no damage}, U_{no damage} are the solar heat gain coefficient and U-value for undamaged glazing. The variables SC_{damaged}, U_{damaged} are the modified values for damaged glazing, reflecting increased solar radiation transmission and heat transfer.

Equation (4) defines how glazing properties change. To achieve this, the EnergyPlus tool developed by the US Department of Energy (DOE) is used as an energy analysis tool. EnergyPlus models energy flows in terms of building energy use, enabling a comprehensive analysis of energy consumption. To compute the energy consumption in addition to S, it is necessary to account for indoor air infiltration through each lost or damaged cladding component. The airflow driven by an extreme wind event is modeled using the airflow network model integrated into EnergyPlus.

### Airflow Network Algorithm Model

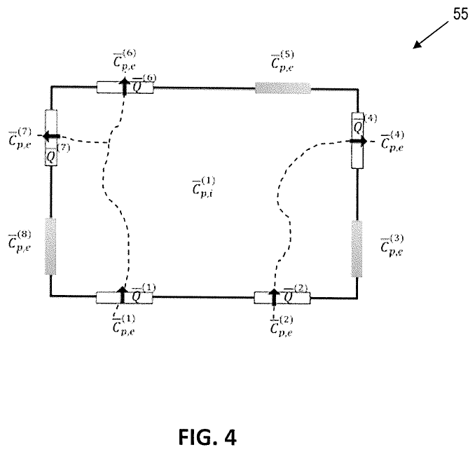

To address outdoor air infiltration due to damage to the building envelope components, the airflow network algorithm model in EnergyPlus allows the wind to drive through damaged components. The model requires that all surfaces with airflow paths be defined and all airflow connections between zones be defined for each external flow surface, wind direction, external pressure coefficient, and airflow rate Q. An example airflow pattern 55 through the interior of the building is demonstrated using an airflow network model in FIG. 4.

To solve the general equation of air mass flow coefficient, often known as the power law equation, the ASTM standard E779 approach equation is generally used. However, in the event of damage to the building envelope components, the power law equation must be adjusted to provide an accurate expression of airflow. The airflow network in EnergyPlus offers a closer match to the universal flow equation at the cost of more sophisticated modeling by defining the conditions under which the air mass flow coefficient was measured and the crack factor for the opening component that was affected by changes in the vent temperature schedule. The air mass flow coefficients {CQ=CQ1, CQ2, . . . , CQj}^{T} through the crack are expressed as a vector that collects the function of the pressure differential across the jth opening for j=1, 2, . . . , N_{Q} using the adjusted power law form. N_{Q} is the total number of openings. In the component level CQj can be expressed as:

$${C}_{{Q}_{j}} = \frac{\overline{{Q}_{j}}}{{F}_{C} \cdot {C}_{T} \cdot {( Δ {P}_{j} )}^{n}} \qquad ( 5 )$$

The term Qj is mean hourly air mass flow through the jth opening in kg/s, F_{C} is crack factor (i.e., F_{C}=1 at opening), C_{T} is a reference condition temperature correction factor, ΔPj is a vector collecting pressure difference across crack through the jth opening, and n is an air flow exponent (i.e., n=0.65). To compute Qj through the hole in the building envelope component, an updated internal pressure coefficient model is required.

### Aerodynamic Analysis: Internal Pressure Coefficients

In buildings with leaks or openings that react to wind induced external pressures, outdoor air can infiltrate and affect the indoor environment, resulting in the development of dynamic internal pressures. This is a crucial factor to consider when designing air infiltration systems, cladding, and buildings. Understanding how these pressures interact is essential for quantifying the air mass flow Q.

An updateable dynamic internal pressure model is used in case the wind event causes a change in the number of external envelope openings resulting from damage. The model development process assumes that the opening size is minimal in relation to the rigid internal space dimensions. Consequently, even if air passes through the openings, the air inside could be seen as stagnant by employing the unsteady-isentropic form of the Bernoulli equation to model the transient airflow at every opening, consisting of interior openings. The mass conservation concept allows for estimating the transient internal pressure fluctuation, which results in the two mechanisms of the system: the enclosed building and the exposed building.

In the case of an enclosed building, it assumes that the building envelope remains intact and prevents any damage that could expose the interior compartments. A normal distribution is observed, while constant internal pressure coefficients are assumed as follows:

$${μ}_{{C}_{p , i}} = - 0.15 + 0.3 \frac{{A}^{+}}{A} \qquad ( 6 )$$

The term A+ refers to the area of the building envelope exposed to positive mean pressure, while A represents the overall exposed area with a standard deviation of the normal distribution of 0.05. The initial internal pressure is maintained statically until a window opens. Then, the building envelope will be exposed, and the dynamic internal pressure model will be applied.

To model the dynamic internal pressure in the exposed building where a hole or leak due to the loss of the building envelope components, the continuity equation yields:

$$\overline{{Q}_{j}} = \frac{1}{{N}_{t}} {\sum }_{t = 1}^{{N}_{t}} {Q}_{j} ( t ) \qquad ( 7 )$$

$${Q}_{j} ( t ) = {A}_{j} {V}_{j} ( t ) = {A}_{j} \sqrt{{\overline{V}}_{H}^{2} \vert {C}_{p , {e}_{j}} ( t ) - {C}_{p , i}^{( {𝒩}_{i} )} ( t ) \vert} \qquad ( 8 )$$

Qⱼ is the mean hourly air mass flow through the j^{th} opening, t and Nₜ are the time steps and the total number of time steps, respectively. Qⱼ(t) is the rate of flow through the j^{th} opening. Aⱼ is the areas of the opening, Vⱼ is the jet velocity flow of air, V_{H} is the mean hourly wind speed at the height of the building, N_{Q} is the total number of openings, C_{p,ej}(t) and C^{(Ni)}_{p,i}(t) are the vectors collecting both the external and internal pressure coefficients of internal compartment Nᵢ, respectively. To qualify, C^{(Ni)}_{p,i} at each opening is represented by a different equation in terms of C^{(Ni)}_{p,i}:

$${\dot{C}}_{p , {i}_{f}}^{( {𝒩}_{i} )} = Θ [ \frac{γ \dot{k} {A}_{j} {P}_{a}}{{L}_{{e}_{j}} {V}_{0}^{( {𝒩}_{i} )} {ρ}_{a}} ( {C}_{p , {e}_{j}} ( t ) - {C}_{p , i}^{( 𝒩} ( t ) ) - {q ( 2 {L}_{{e}_{j}} )}^{- 1} {{V}_{0}^{( {𝒩}_{i} )} ( γ {kA}_{j} {P}_{a} )}^{- 1} \vert {\dot{C}}_{p , i}^{( {𝒩}_{i} )} ( t ) \vert {\dot{C}}_{p , i}^{( {𝒩}_{i} )} ( t ) ] \qquad ( 9 )$$

The variable γ is the specific heat ratio for air (i.e., 1.4 for adiabatic air), k is the discharge coefficient (=1\sqrt{ } C₁), A is the diagonal matrix collecting the areas of the opening, Pa is the barometric pressure (i.e., 101300 Pa), Le is the diagonal matrix collecting the inertia coefficient (i.e., \sqrt{ } π/4), V₀^{(Ni)} is the volume of the internal compartment Ni, ρₐ is air density (i.e., 1.225 kg/m³), and q is the dynamic pressure at the building top. C₁ is the loss coefficients of the air slugs of each opening; C_{p,i}^{(Ni)} is the diagonal matrix collecting the change in internal pressure coefficient through each opening with their vector, while θ is a connectivity matrix that identifies the nominal external and internal pressure coefficients for each opening.

Numerical techniques are needed to solve the nonlinear and coupled system of equation (9) while considering the possibility of variations in the damage condition of each envelope component throughout the windstorm's progress. The Runge-Kutta-Fehlberg method with 4th-order precision with an error estimator of order 5th-order due to its computational efficiency and stability is used. Therefore, the building envelope represents the separation of indoor and outdoor environments, which influences energy efficiency and indoor air infiltration. A building performance assessment is required to effectively address building envelope damage and air infiltration in buildings exposed to extreme wind events.

### Building Envelope Damage Model

The condition of the building envelope components must be known prior to the energy analysis to determine the energy demand on wind-excited buildings. Thus, the assessment of building envelope damage requires an iterative performance analysis that quantifies the extent of the impact of building drift-induced and pressure-induced damages on energy demand. This can be done through PBWE and the fragility assessment approach, which uses probabilistic models to calculate the failure probabilities based on structural and aerodynamic responses.

### Fragility Assessment Methodology

The current practice to evaluate the performance of wind-excited structures is to use fragility functions to probabilistically determine the damage state of each component of the building. The fragility function, FDSk(edp), mathematically provides the probability that a component incurs a certain damage state conditioned on the engineering demand parameter edp and is usually expressed by a lognormal distribution as follows.

$${P}_{{DS}_{k}} ( edp ) = P ( DS \geq {ds}_{k} \vert edp ) = Φ ( \frac{ln ( edp / {x}_{m} )}{β} ) \qquad ( 10 )$$

The term DSₖ denotes the kth damage state (e.g., glass crack, window blown out), xₘ and β are the median and dispersion parameters of the lognormal distribution, respectively, φ is the standardized normal distribution function and k=1, . . . ,N_{DS} represent possible damage states for the given component. In wind-excited buildings, wind-induced damage can be initiated by two major mechanisms with different associated demand parameters edp (i.e., peak inter-story drifts and net pressures). This can be assessed using multiple coupled fragility functions, and each set of damage states will be dependent upon the occurrence of the other. This coupling damage model can be carried out by time stepping throughout the whole wind event to model the progressive damage of the building envelope.

### Drift-Induced Damage

The damage caused by excessive inter-story drift is expected to be characterized by j=1, . . . , N_{Dr} sequential damage states for any given envelope component. The engineering demand parameters (edps) are taken to be the instantaneous drift ratios occurring during the event, such as edp=Dr(t) for t∈[0,T] with d_{Ni,x}(t), and d_{Ni,y}(t) assessed as follows:

$$Dr ( t ) = \frac{1}{\text{?}} \vert [ \begin{matrix}{x}_{Ni} ( t ) - {D}_{{N}_{i} y} {ϑ}_{Ni} ( t ) \\ {y}_{{N}_{i}} ( t ) - {D}_{{N}_{i} x} {ϑ}_{{N}_{i}} ( t )\end{matrix} ] \begin{matrix}- \\ -\end{matrix} [ \begin{matrix}{x}_{{N}_{i} - 1} ( t ) - {D}_{{N}_{i} - 1 , y} {ϑ}_{{N}_{i} - 1} ( t ) \\ {y}_{{N}_{i} - 1} ( t ) - {D}_{{𝒩}_{i} - 1 , x} {ϑ}_{{N}_{i} - 1} ( t )\end{matrix} ] \vert \qquad ( 11 )$$

$$\text{?} \text{indicates text missing or illegible when filed}$$

Once the edp is obtained in terms of inter-story drift ratio Dr(t), a set of thresholds related to the fragility functions needs to be created in order to evaluate the development of drift-induced damage throughout the course of the wind event for a particular suite of sequential fragility functions, F_{Drj} for j=1, . . . , N_{Dr}. To accomplish this, two steps can be used. Step 1: generate a realization (u) of a uniform random number in the range [0, 1]. Step 2: For every fragility function, estimate the damage threshold, C_{Drj}. Therefore, finding an upper threshold that is less than Dr(\tilde{ } t) is all that is required to assess the drift-based damage condition of any given envelope component at t=\tilde{ }t. This threshold will indicate the current status of drift-induced damage in the envelope component.

### Pressure-Induced Damage

To consider pressure-induced damage, a similar fragility-based approach can be used to evaluate the damage state of any given building envelope component. In this case, edp is taken as the instantaneous equivalent pressure, P_{eq}(t). Through the initial set of N_{Peq} pressure thresholds (C_{peq1}≤C_{peq2}≤, . . . , ≤C_{pNpeq}), each component of the envelope can be associated with a set of N_{Peq} sequential fragility functions that will be assessed during the event. These thresholds are then compared to the pressure demand throughout the event in [0, T]. During a wind event, the structural integrity of the glass is subject to fluctuation depending on the duration of the applied load and the varying pressures exerted on the window panes. Thus, evaluating the cumulative effect of variations in wind pressure throughout the course of the storm is essential. Thus, glass failure during extreme wind events is typically caused by static fatigue/delayed failure, which cannot be determined just by the net peak pressure. In order to address this fact, the following temporal development of the equivalent pressure P_{eq} is used as the demand parameter for glass panels:

$${P}_{eq} ( t ) = {( \frac{1}{{t}_{ref}} {\sum }_{i = 1}^{i = \text{?}} ( {[ {P}_{n} ( {t}_{i} ) ]}^{s} {t}_{\text{?}} ) )}^{1 / s} \qquad ( 12 )$$

$$\text{?} \text{indicates text missing or illegible when filed}$$

The variable t_{ref} is time duration of equivalent constant pressure (i.e., 60 sec), Pₙ(tᵢ)
Is net pressure at a particular time instant, ti=time duration of net pressure Pₙ(tᵢ) of instants being summed, and s is constant (i.e., 16).

### Damage Coupling

In order to assess the total damage and energy consumption resulting from a specific extreme wind event, a progressive damage model is needed. Hence, the model needs to take into account the general relationship between the damage caused by wind force and the component's capacity to withstand local wind pressure. Two sets of sequential damage thresholds that illustrate the sensitivity of each component to pressure and drift-induced damage may be used.

Each component has two sets of sequential damage thresholds that indicate its susceptibility to damage caused by pressure and drift. During a wind event, the occurrence of the related damage state is indicated if any of the damage thresholds are exceeded. The way pressure and drift damage states interact is explained through deteriorating fragility functions. Meanwhile, uncertainty in the thresholds is illustrated by sets of sequential fragility functions of the i^{th} envelope component. The fragility functions between demands and damage are summarized in Table 1, where the cladding component refers to damage affecting the entire cladding, while the glass panel denotes damage limited to a single glazing panel within the cladding component.

TABLE 1

| Component Damage | Demand (edp) | Damage state | Median | Dispersion | Mean | Std | Unit |
|---|---|---|---|---|---|---|---|
| Cladding component | Drift ratio | Gasket seal failure | 0.0312 | 0.472 | — | — | rad |
| (C [symbol] ) | (Dr) | (DS [symbol] ) | | | | | |
| Cladding component | Drift ratio | Glass hairline cracking | 0.0322 | 0.472 | — | — | rad |
| (C [symbol] ) | (Dr) | (DS [symbol] ) | | | | | |
| Cladding component | Drift ratio | Glass failure | 0.0407 | 0.472 | — | — | rad |
| (C [symbol] ) | (Dr) | (DS [symbol] ) | | | | | |
| Glass panel | Net pressure | Glass blowout | — | — | 4.45 | [symbol] | kPa |
| (C [symbol] ) | (P [symbol] ) | (DS [symbol] ) | | | | | |

[symbol]

indicates data missing or illegible when filed

To take into account the interactions between demands and damage, the damage states DS_{Peq} and DS³_{Dr} are considered to be failures for the glazing unit. Additionally, it is anticipated that while the glass cracking in damage state DS₂_{_{Dr}} would weaken the glass panels, the gasket seal failure in damage state DS¹_{Dr} would not affect the strength of the glass. The unit capacity to endure P_{eq} is estimated to drop by 10% on average when DS²_{Dr} occurs. Reductions were represented by a truncated normal distribution with a range of [0,1] and were assumed to have a coefficient of variation of 0.1 in order to account for uncertainty.

The final damage states in this framework are set to be consequences of damage for each envelope component as follows: N_{DSDr} vector containing the number of envelope components associated with each damage state caused by drift, and N_{DSPeq} vector containing the number of envelope components associated with each damage state caused by pressure. The selection of consequences is certainly not restricted to those implied previously mentioned. As a result, the set described here ought to be thought of as a representative selection.

### Building Description

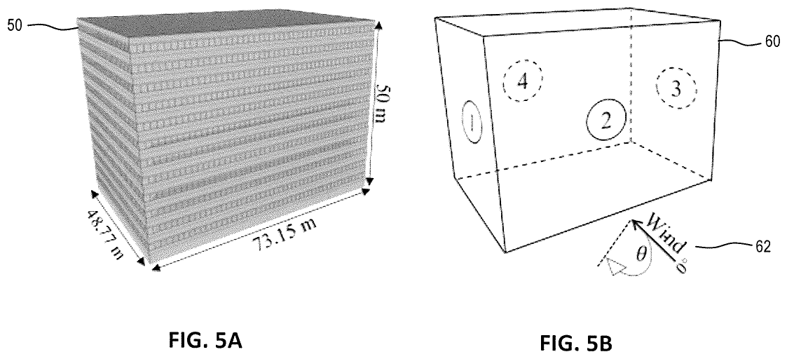

A three-dimensional (3D) view of the building 50 under consideration for the simulation is illustrated in FIG. 5A, and a surface layout 60 of the building and wind attack angle direction is illustrated in FIG. 5B. The building 50 is a rectangular 12-story structure plus a basement with a total height of 50 m (164 ft). Each floor level has a constant height of 3.96 meters (13 ft). The building has a width of 48.77 m (160 ft) and a length of 73.15 m (240 ft).

The building 50, for example, is sited in Miami, Florida, making it vulnerable to the region's hurricane-prone environment. Milepost 1450 of the directional hurricane database provided by the National Institute of Standards and Technology (NIST) was taken into consideration for calibrating the hazard model. The risk category II with mean recurrence interval (MRI)=700 years was selected based on the American Society of Civil Engineers ASEC 7-22 specification, which leads to a mean hourly wind speed at the height of the building of VH=50.58 m/s.

The length of the windstorm had been determined at T=1 h since wind impacts tend to be measured over an hour. A ⅓ rigid scale model of the building was used to collect wind tunnel data, from which a total of K=192 dynamic external pressure coefficients C_{p,e} were recorded. The data was measured with a sampling frequency of 15 Hz for 10 minutes in a given model scale, with wind speed at 10 meters at 22 m/s, with a power law coefficient α of 5. The probabilistic analysis is done using a Monte Carlo simulation technique. Hence, a proper orthogonal decomposition stochastic simulation model was chosen to generate the stochastic C_{p,e}(t) [46, 47]. The first 25% of spectral modes were chosen to simulate C_{p,e} at a sampling frequency of 2 Hz. The relationship between hurricane-induced facade damage and building energy consumption using three case scenarios that reflect progressive states of vulnerability and mitigation will be evaluated. The case studies are as follows.

Case 1—Baseline Model: Represents the intact building envelope with no damage. This scenario reflects standard energy performance under undisturbed operating conditions.

Case 2—Post-Hazard Damaged Model: Represents a severely damaged building envelope following extreme wind loading. The damage is the result of pressure-induced failures and inter-story drift, which compromise the integrity of fenestration systems.

Case 3—Post-Hazard Mitigated Model: Maintains the same hazard exposure as Case 2 but employs an improved glazing system designed to enhance resistance to damage while minimizing energy loss.

As will be discussed below, the comparison between Case 1 and Case 2 reveals a 58% increase in energy consumption due to envelope failures. This drastic increase stems from uncontrolled air infiltration and thermal exchange resulting from broken and penetrated windows, which compromise the conditioned space to force HVAC systems to operate at higher capacities to maintain thermal comfort. In Case 2, damage is concentrated on windward-facing surfaces, specifically Surface 2, where dynamic wind pressure and building sway interact to cause localized failures.

The glazing damage is classified into two distinct types:

Damaged Windows: Defined as damage to the outer glazing layer only. These are caused by pressure-induced failure on the windward surface, leading to thermal bridging and increased solar gain but no direct airflow penetration.

Broken Windows: Defined as the failure of both inner and outer glazing layers, resulting in openings in the building envelope 24. These openings allow uncontrolled wind-driven airflow into the interior, significantly increasing HVAC loads. Damage of this nature is primarily due to combined pressure loading and structural drift.

In Case 2, approximately 32.2% of the windows experienced broken windows, while an additional 19.1% experienced damaged windows, leading to direct air exchange between indoors and outdoors. Notably, most of the damage was concentrated on windward surface 2, where pressure-induced failures were most severe.

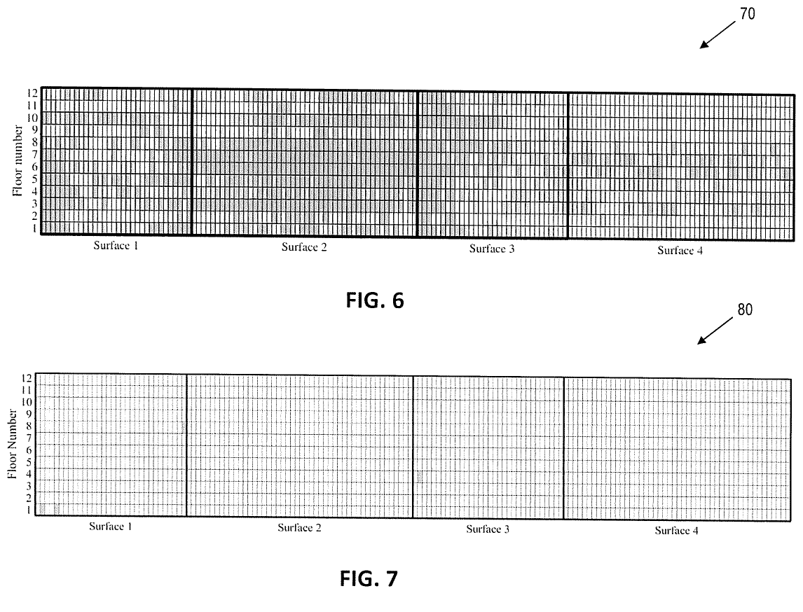

The post-event wind-induced damage 70 (Case 2) to the building 50 is illustrated in FIG. 6, and the post-event wind-induced damage 80 (Case 3) to the building 50 with an enhanced building envelope is illustrated in FIG. 7. These figures visually summarize the final glazing condition after an extreme wind event where the purple indicates windows with outer-layer breakage, red indicates fully penetrated glazing (both layers damaged) and white indicates undamaged glazing.

To address the vulnerabilities exposed in Case 2, Case 3 employs an upgraded glazing configuration:

Case 2 Glazing: ¼ in. (6 mm) inner Annealed/¼ in. (6 mm) outer Annealed Laminated.

Case 3 Glazing: ¼ in. (6 mm) inner Annealed/½ in. (13 mm) outer Annealed Laminated.

The thicker outer pane and optimized interlayer in Case 3 improve both the impact resistance and energy-absorbing capacity of the facade. The post-hazard energy usage of Case 3 shows no difference compared to the undamaged baseline (Case 1), demonstrating the effectiveness of the mitigation strategy in restoring envelope performance.

Additionally, Case 3 exhibited fewer than Case 2 with only four broken windows which resulted in reduction of 99.3%, indicating that the upgraded glass configuration not only preserved structural integrity under wind loading but also contributed to maintaining thermal performance at the same designed operation for the HVAC systems and limiting post-event energy loss.

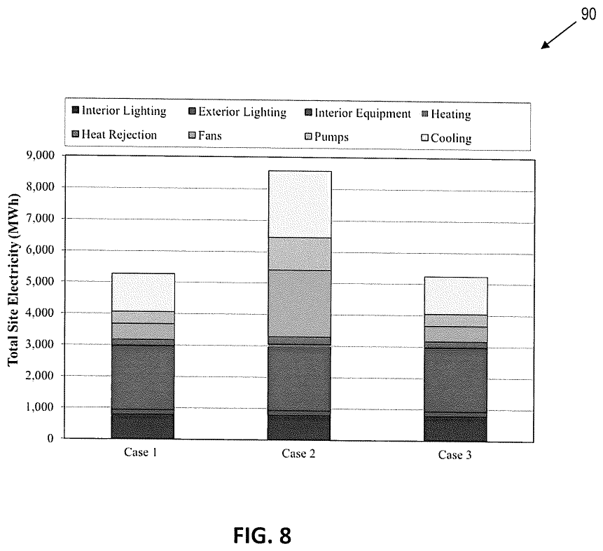

An energy consumption stacked bar chart 90 for the three different design scenarios is illustrated in FIG. 8. Notably, there is a dramatic reduction of 16.81% in peak hourly demand for the HVAC system in cooling, which considerably lowers the operational stress during the recovery period. In addition, the building demonstrates a 46.35% decrease in total hurricane season energy consumption for HVAC operations compared to the severely damaged scenario in Case 2. This mitigation in Case 3 reflects long-term energy savings and enhanced performance under post-hazard conditions.

As part of the modeling, the following costs may be determined. A first cost is an energy consumption cost based on the estimated energy consumption by the building envelope 24 based on the wind-induced damage (Case 2). A second cost is a building envelope cost to enhance the building envelope (Case 3) based on the damage analysis. These costs allow an evaluator to decide how future buildings can be designed with a focus on energy savings.

A first analysis may be made by the evaluator on a revised glazing design that reflects insights from the model 30 regarding the relationship between façade damage and energy loss. Based on this, the number of broken and/or damaged windows may be significantly reduced. This mitigates the effects of hurricanes on energy loss. This is a design decision directly influenced by the simulation results.

A second analysis may be made to show that HVAC peak load increases significantly when windows are broken and/or damaged during a hurricane, as predicted by the model 30. Such an increase can affect the initial design and sizing of the HVAC. This finding supports the development of an HVAC system optimized for both energy efficiency and resilience in the face of a natural hazard.

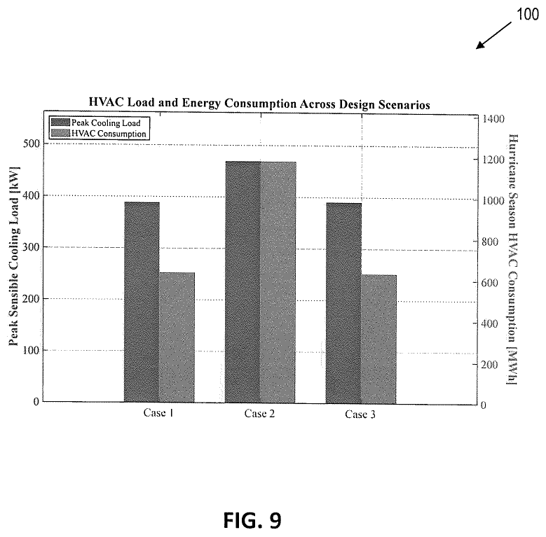

A comparison of peak cooling load and total HVAC energy consumption chart 100 during hurricane season for the three different design scenarios is illustrated in FIG. 9. The comparison of peak sensible cooling load (KW) is in blue, and total HVAC energy consumption during the hurricane season (MWh) is in orange. The left axis represents the peak cooling demand required for HVAC system sizing, while the right axis indicates the corresponding seasonal energy usage for each design scenario (Case 1, Case 2, and Case 3).

A visual outline for the model 30 is illustrated in FIG. 10. In Block 102, wind intensity on the building is determined. In Block 104, a dynamic motion of the building 50 is determined over time. This includes sway of the building 50 based on the wind intensity. In Block 106, external air pressure on the building 50 is determined, and then in response to a window breaking, internal air pressure is determined. A possible air flow pattern using an airflow network model is determined. The white rectangular shapes represent leaks or holes, and the blue rectangular shapes represent closed windows. In Block 108, an estimated energy consumption 42 is displayed.

The above-described integrated assessment model 30 serves as a powerful tool for both engineers and architects in selecting and optimizing facade systems based on their site-specific environmental hazards and performance objectives. By quantifying the impact of wind-induced damage on building energy consumption, this model enables data-driven decision-making during the early stages of design and material specification, helping professionals balance structural resilience with long-term energy efficiency.

Importantly, without such a model, the post-hazard performance of a given façade configuration, such as that represented in Case 2, would not be scientifically quantifiable. Designers would otherwise rely on approximate estimation methods that often overestimate or underestimate damage extent and its cascading effects on building energy use. This not only compromises design accuracy but may also result in costly inefficiencies or underperformance in real-world applications. The algorithm 30 thus strengthens progress in disaster resilience by connecting structural engineering and energy efficiency, thus offering insights into mitigation strategies and policymaking. This finding aids the overarching objective of establishing resilient and energy-efficient built environments in hurricane-prone regions by enhancing the reliability of energy assessments conducted following an extreme wind event. By addressing these challenges, the algorithm 30 aids in advancing performance-based design and energy resilience while emphasizing the need for integrated energy and structural modeling approaches.

### CONCLUSION

The computational framework as discussed above is directed to the probabilistic evaluation of energy consumption in wind-excited buildings. The developed process makes it possible to estimate the expected energy consumption in any given building and location. The framework incorporates multiple parts, including wind tunnel-informed aerodynamics and dynamic response analyses, internal pressure dynamics, and fragility-based damage modeling to estimate energy demands through EnergyPlus simulations that use an airflow network model, all within a Monte Carlo simulation algorithm.

An important aspect of the framework is the explicit modeling of interdependencies between damage states caused by structural dynamic responses and damage states caused by excessive net pressure on building envelope components. Furthermore, it identifies the relationships between damage states and energy demand parameters to compute expected energy consumption.

A 12-story steel-framed office building with laminated dual-pane glass cladding serves as the case study to illustrate the applicability of the framework. The analysis revealed an average 23.1% increase in energy consumption attributed to wind-induced damage. The critical impact of envelope damage on building energy performance was highlighted by the strong correlation encountered between energy consumption and the number of broken windows. The spatial pattern of damage had a significant impact on air infiltration, resulting in varying energy consumption outcomes in events. The findings highlight the benefits of the framework in offering comprehensive and site-specific insights to guide the analysis and design of efficient and resilient building systems.

The probabilistic framework can be extended for future research that aims to quantify the impact of environmental risks related to indoor air quality (IAQ), thermal comfort, and carbon footprint emissions. Quantifying these factors can inform decision makers and engineers about how people feel and their well-being in their daily activities during the recovery period. For example, if a space is too hot or too cold, it can lead to discomfort and decreased productivity, or poor IAQ can lead to a range of health problems.

Another essential research need is to quantify the effects of predicted increases in wind intensity on the performance of structural and energy systems. This increase in future hazard intensity can cause more damage to the building envelope and expose the building to future weather conditions. Hence, understanding the impact of future conditions can help design more resilient and energy-efficient buildings. To this end, the framework for the probabilistic evaluation of energy consumption in wind-excited buildings, used in conjunction with the results of the suggested structural and energy performance studies, allows for a more accurate estimate of energy consumption in damaged buildings and improved resilience planning through energy-aware structural assessments in terms of adaptation strategies that could be implemented in both the short and long term.

Many modifications and other embodiments will come to the mind of one skilled in the art having the benefit of the teachings presented in the foregoing descriptions and the associated drawings. Therefore, it is understood that the foregoing is not to be limited to the example embodiments, and that modifications and other embodiments are intended to be included within the scope of the appended claims.

1. A method for accessing energy performance due to wind-induced damage on a building envelope for a building, the method comprising:
performing a hazard analysis on the building envelope using site-specific data and probabilistic wind assessments for a hazard intensity;
performing an aerodynamic analysis to evaluate how the probabilistic wind assessments interact with the building envelope;
performing a structural analysis to assess how the building envelope responds to wind-induced loads;
performing a damage analysis to evaluate wind-induced damage to the building envelope in response to the wind-induced loads; and
performing an energy analysis comprising:
determining post recovery weather conditions for a recovery period after the hazard intensity has ended,
performing an aerodynamic analysis to evaluate how the post recovery weather conditions interact with openings in the building envelope based on the wind-induced damage,
determining airflow within the building envelope based on the wind-induced damage, and
estimating energy consumption by the building envelope based on the airflow.

2. The method according to claim 1 wherein the hazard intensity has a set timeframe associated therewith, and an average wind speed at a height of the building is determined for the set timeframe.

3. The method according to claim 1 wherein the aerodynamic analysis, the structural analysis and the damage analysis are iteratively performed over a timeframe set for a duration of the hazard intensity.

4. The method according to claim 1 wherein the aerodynamic analysis and the structural analysis are performed in parallel, with data from the structural analysis being provided to the aerodynamic analysis, and with data from the aerodynamic analysis being provided to the structural analysis.

5. The method according to claim 1 wherein the aerodynamic analysis determines pressure external to the building envelope and pressure internal to the building envelope during the hazard intensity, and the structural analysis determines a drift of the building during the hazard intensity.

6. The method according to claim 1 wherein openings in the building as determined by the damage analysis are fed back into the aerodynamics analysis for updating.

7. The method according to claim 1 wherein the post recovery weather conditions include an external air pressure and varying wind patterns.

8. The method according to claim 1 wherein the estimated energy consumption provides for design of an HVAC system for the building optimized for both energy efficiency and resilience in response to wind-induced damage.

9. The method according to claim 1 comprising:
determining a building envelope cost to enhance the building envelope based on the damage analysis; and
determining an energy consumption cost based on the estimated energy consumption by the building envelope based on the wind-induced damage.

10. The method according to claim 1 wherein the building envelope separates an inside of the building from an environment outside of the building.

11. The method according to claim 1 wherein the hazard intensity corresponds to a hurricane category classification.

12. The method according to claim 1 wherein the aerodynamic analysis determines how a distribution of pressure on external surfaces of the building envelope varies based on wind speed and direction.

13. The method according to claim 1 wherein the energy analysis uses an internal pressure model to access internal air infiltration when the building experiences damages that allows air to enter through the damaged components of the building envelope.

14. A computing device comprising;
a memory configured to store a building envelope for a building, and an energy performance prediction algorithm for wind-induced building damage;
a processor coupled to the memory and configured to execute the energy performance prediction algorithm to perform the following:
perform a hazard analysis on the building envelope using site-specific data and probabilistic wind assessments for a given hazard intensity,
perform an aerodynamic analysis to evaluate how the probabilistic wind assessments interact with the building envelope,
perform a structural analysis to assess how the building envelope responds to wind-induced loads,
perform a damage analysis to evaluate wind-induced damage to the building envelope in response to the wind-induced loads, and
perform an energy analysis comprising:
determine post recovery weather conditions for a recovery period after the hazard intensity has ended,
perform an aerodynamic analysis to evaluate how the post recovery weather conditions interact with openings in the building envelope based on the wind-induced damage,
determine airflow within the building envelope based on the wind-induced damage, and
estimate energy consumption by the building envelope based on the airflow; and
a display coupled to the processor and configured to display the estimated energy consumption by the building envelope based on the wind-induced damage.

15. The computing device according to claim 14 wherein the hazard intensity has a set timeframe associated therewith, and an average wind speed at a height of the building is determined for the set timeframe.

16. The computing device according to claim 14 wherein the aerodynamic analysis, the structural analysis and the damage analysis are iteratively performed over a timeframe set for a duration of the hazard intensity.

17. The computing device according to claim 14 wherein the aerodynamic analysis determines pressure external to the building envelope and pressure internal to the building envelope during the hazard intensity, and the structural analysis determines a drift of the building during the hazard intensity.

18. The computing device according to claim 1 wherein openings in the building as determined by the damage analysis are fed back into the aerodynamics analysis for updating.

19. The computing device according to claim 1 wherein the post recovery weather conditions include an external air pressure and varying wind patterns.

20. A non-transitory computer readable medium having computer-executable instructions for causing a computing system to access energy performance due to wind-induced damage on a building envelope for a building, with the computing system to perform steps comprising:
performing a hazard analysis on the building envelope using site-specific data and probabilistic wind assessments for a given hazard intensity;
performing an aerodynamic analysis to evaluate how the probabilistic wind assessments interact with the building envelope;
performing a structural analysis to assess how the building envelope responds to wind-induced loads;
performing a damage analysis to evaluate wind-induced damage to the building envelope in response to the wind-induced loads; and
performing an energy analysis comprising:
determining post recovery weather conditions for a recovery period after the hazard intensity has ended,
performing an aerodynamic analysis to evaluate how the post recovery weather conditions interact with openings in the building envelope based on the wind-induced damage,
determining airflow within the building envelope based on the wind-induced damage, and
estimating energy consumption by the building envelope based on the airflow.
